(19) United States
(12) Patent Application Publication
(10) Pub. No.: US 2026/0268750 A1
(43) Pub. Date: Sep. 10, 2026

(54) INTRUSION DETECTION SYSTEM FOR FENCE

(71) Applicant: A-1 FENCE PRODUCTS COMPANY PVT LTD, MUMBAI (IN)

(72) Inventors: Saurabh Gupta, Mumbai (IN); Rahul Abhayankar, Mumbai (IN); Chandrashekhar Sahu, Dhamtari (IN); Anuruddh Tiwari, Tikamgarh (IN); Nitin Katare, Mumbai (IN)

(73) Assignee: A-1 FENCE PRODUCTS COMPANY PVT LTD, MUMBAI, MH (IN)

(21) Appl. No.: 19/166,870

(22) PCT Filed: Mar. 21, 2024
(86) PCT No.: PCT/IN2024/050294

§ 371 Date: Sep. 19, 2025

(30) Foreign Application Priority Data
Mar. 21, 2023 (IN) 202321012625

(51) Int. Cl. G08B 13/22; G01R 27/16; G01V 3/02; G01V 3/38

(52) U.S. Cl. CPC G08B 13/22; G01R 27/16; G01V 3/02; G01V 3/38

(57) ABSTRACT

The disclosed invention is an intrusion detection system (1) for fencing, which can detect any cut to the fence even as an attempt is being made. It comprises of a fence barrier which is an electricity conducting, insulated, 1^{st} sensing element (38) extending horizontally between fence posts (10, 11, 12), and a low voltage impedance detection system (FIG. 5). The low voltage impedance detection system comprises a set of fixed resistors (16) and an impedance monitoring assembly which is in connection with an intrusion alert unit. (FIG. 8). The preferred sensing element is a honeycomb mesh fabric (7).

### CROSS-REFERENCE TO RELATED APPLICATIONS

The present application is a continuation of an International Application No. PCT/IN2024/050294 with a filing date of 21 Mar. 2024, the entire disclosure of which is incorporated herein by reference for all purposes. The present application claims the benefit of Indian priority application No. 202321012625 with a filing date of 21 Mar. 2023, the entire disclosure of which is incorporated herein by reference for all purposes.

### FIELD OF THE INVENTION

The present invention relates to an intrusion detection system for use in perimeter fencing to enable alerting an intrusion or cutting through such fence structures, using non-lethal electric signals. More particularly, the present invention relates to a system whereby an attempt for intrusion when made is alerted by a signal indicating a cut-through type intrusion is being attempted on the perimeter fence.

### BACKGROUND OF THE INVENTION

Various means have been employed till date to detect intrusion of protective perimeter fences. When an insulated electrical cable is flexed, or when pressure is applied thereto, the resulting stress produced in the previously uncharged dielectric material of the cable by the movement results, due to the triboelectric effect, in the generation of a very small electric field signal which may be sensed with appropriate sensing circuitry. When such a cable is attached to a flexible wall structure or fence, for example a chain-link fence, minute flexing of the cable due to vibration of the fence results in the generation of an electric field signal corresponding to these vibrations. Electric field signals will be produced by fence vibrations, and hence electrical cable vibrations, which are desired to be detected, i.e. vibrations caused by attempted intrusions, as well as by fence vibrations which are not desired to be detected, i.e. vibrations from extraneous sources, such as wind, nearby freight trains and trucks, etc., will cause electric field signals. Since the detection of these extraneous sources caused signals could lead to false alarms, special signal processing is required in order to distinguish signals originating from intruder related vibrations as against those originating from extraneous source related vibrations.

In order to provide adequate protection for a wall or fence, it is desirable to know whether an intruder is attempting to cut through the fence or is attempting to climb over the same. In general, the signals resulting from attempts to cut through a fence are of short duration, are abrupt, and are generally repeated a number of times within a predetermined short period of time. On the other hand, signals corresponding to attempts to climb over a flexible fence generally have longer duration in that they have a lower base frequency than cut-through type vibration signals and persist for a longer period of time.

Electric fences are often used for security purposes to restrict unauthorized entry to certain areas such as industrial premises. They are also used for containment in detention centers and for agricultural fields. Electric fences normally include a number of posts from which numerous non-insulated wire conductors are strung such that the conductors are insulated from the posts and therefore the ground. The conductors are coupled to an energizer that periodically outputs a high voltage pulse to energize the conductors so that intruders will receive a small electric shock if they contact the energized conductors. While the voltage may be very high, such as up to 10,000 Volts peak, the time of the pulse is very short in order to be safe, typically of the order of 100 microseconds.

The intruder receives a shock by completing the circuit from the energizer, via the live wires to ground and back to the energizer ground terminal. The spacing and height of the wires is such that it is difficult to gain access to the protected area without contacting the wires. The live wires are often interleaved with grounded wires so as to make a circuit even if the intruder attempts to insulate him or herself from the ground but touches more than one wire. If the wires are cut or shorted to ground, a monitoring circuit connected to the electrical “end” of the live wires detects the change in voltage and can signal or sound an alarm or trigger a call to a guard center. This monitoring is typically achieved by measuring the peak voltage. If the peak voltage falls below a predetermined threshold at the fence, an alarm is generated.

Traditionally, detection of physical intrusion through a fence that is done by cutting, climbing, damaging the fence, involves fixing or installing sensing elements on the fence. The traditional methods of intrusion detection on the fence use technologies like Micro Electro Mechanical System (MEMS) sensors. These are used to detect acceleration or angular motion. When these sensors are used, the mechanism of sensing a cut in the fence is by the mechanical vibration that is generated when a cut attempt is made on the fence. These mechanical vibrations are sensed by the MEMS sensor. The MEMS sensor along with the associated circuit analyses the acceleration or the angular motion signal and alerts the system. Here, the effect of a ‘cut attempt’ passes through various stages before a reliable detection is made. The effect of the cut on the fence in the form of vibration could be very feeble, and for it to be effective, several MEMS have to be placed on the fence at close spacing.

Improvements in electric fencing in recent years include live wire systems being introduced, whereby, instead of alternating live and grounded wires on the fence, there are two polarities or phases of live wires. These are not desirable, since in trying to meet the objective of deterrence or detection of an intruder, it could still cause grievous accidents. An existing low voltage detection circuit cannot be added to these fences since there are no ground or earthed conductors in these fences. Although safe low voltage electrical fences are desirable, the variation in the resistance when one of the wires, rods, or bars is cut, is very low, and low resistance measurement is impractical and costly. The resistance will change from low value to high value only when all the elements are cut, i.e., only when the fence is fully breached.

Hence, a safe, effective intrusion detection system with a measurable parameter, which can alert an intrusion while it is being attempted, is desirable.

### SUMMARY OF THE INVENTION

In its main aspect, the present invention discloses an intrusion detection system for fencing comprising an electricity conducting 1^{st} sensing element connected to a low voltage electrical source, through an impedance detection system. The sensing element, which is insulated, is supported between fence posts. The intrusion to the fence is detected through an impedance detection system comprising a set of fixed resistors (16) and an impedance monitoring assembly in connection with an intrusion alert unit.

In another aspect of the invention, the fence posts are mounted on a ground surface, and a virtual capacitor circuit is created by 1^{st} the sensing element acting as a first plate and the ground surface acting as a second plate.

In yet another aspect of the invention, the intrusion alert unit which is in connection with the impedance monitoring assembly, comprises an input means, display means, output means, and central monitoring software.

In a further aspect of the invention, the 1^{st} sensing element is a length of honeycomb fabric (7), made of a set of horizontally aligned insulated wires extending between fencing posts, each of the wires of the set having a 1^{st} end (9) and a 2^{nd} end (9′).

In a working aspect of the invention, the 1^{st} end of the first wire is connected to a terminal (18), within the impedance monitoring assembly which is the low voltage source, and the 2^{nd} end is shorted to the immediately adjacent wire. Each of the wires of the honeycomb fabric, except the first wire (3) are connected to a fixed resistor (16) at its 1^{st} end (17), and the circuit is continued by shorting the 2^{nd} end of each wire (9′) to the 2^{nd} end of its immediately adjacent wire. The other ends of all the fixed resistors (16) are shorted with their immediately adjacent resistor. All the wires of the honeycomb fence passing through their respective resistor remain in circuit connection to their immediately adjacent wire to form a continuous electrical circuit. The 1^{st} of the set of fixed resistors (16) is connected to the other terminal (18′) of the resistance to voltage convertor in the impedance measuring assembly through a connection interphase. The fixed resistors at each end of the wires are secured to the fence post. The impedance monitoring assembly is connected to a low voltage source (28), and comprises at least one circuit monitoring unit, resistance to voltage convertor, and an anolog-digital convertor (ADC), which are all in circuit connection to the microcontroller, and placed within a printed circuit board (PCB) (44). The PCBs (44) are secured to the fence post, preferably the straining fence post (11, 11′)

In an advanced aspect of the invention, the fence posts, which may be end fence posts, or intermediary fence posts or straining fence posts (11, 11′) have upwardly extending Y arms (48) with recesses (52), and the Y-arms (48) supporting the 2^{nd} sensing elements (40), preferably concertina coils, between two or more fence posts. The ends of the concertina coil are in circuit connection with the circuit monitoring unit and the microcontroller within the PCB (44). Ideally, the PCBs (44) are placed within the recesses (52) of the Y arms (48).

In a more advanced aspect of the invention, the microcontroller present within the PCB (44) is in wireless connection with the intrusion alert unit.

In a working aspect of the invention, any impedance on the sensing element is measured by the microcontroller and displayed on the display means of the intrusion detection system.

In yet another interesting working aspect of the invention, an object approaching the 1^{st} and 2^{nd} sensing elements, is detected by the virtual fence capacitor circuit, and the change in capacitance is measured by a multi-meter or directly by the microcontroller and conveyed to the intrusion alert unit by the impedance measurement unit, and displayed on the display means.

### BRIEF DESCRIPTION OF THE DRAWINGS

FIG. 1 illustrates a fence;

FIG. 2 illustrates a honeycomb fence;

FIG. 3 illustrates a honeycomb fence with fence post;

FIG. 4 illustrates fence posts;

FIG. 5 illustrates a honeycomb fence and the placement of resistors within the impedance detection system;

FIG. 5a is a representative illustration of a circuit of an impedance monitoring assembly;

FIG. 6 illustrates a honeycomb mesh panel with a 1^{st} sensing element and a 2^{nd} sensing element;

FIG. 7 illustrates a Y arm of a fence post;

FIG. 8 is a flow chart of an impedance monitoring assembly with a 1^{st} sensing element and a 2^{nd} sensing element;

FIG. 9A illustrates a plurality of electrical lines of a fence in a dielectric of a virtual capacitor;

FIG. 9B is a representation of an intruder in a dielectric of a fence;

FIG. 10 illustrates a fence with an arrangement of a capacitor and a resistor;

FIG. 11 is a representation of an intruder near a fence with an arrangement of a capacitor and a resistor; and

FIG. 12 is a representation of an intruder in close proximity of a fence with an arrangement of a capacitor and a resistor.

### DETAILED DESCRIPTION OF THE INVENTION

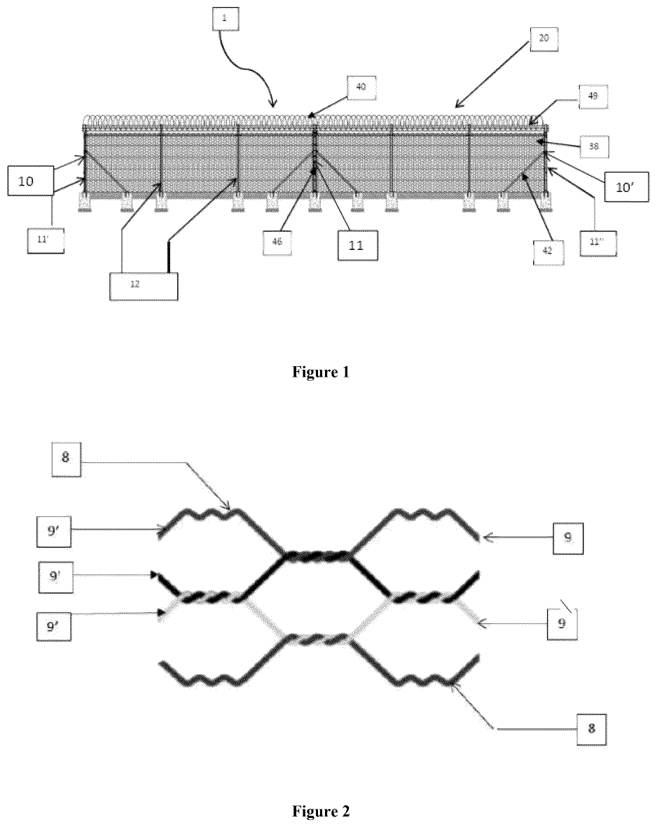

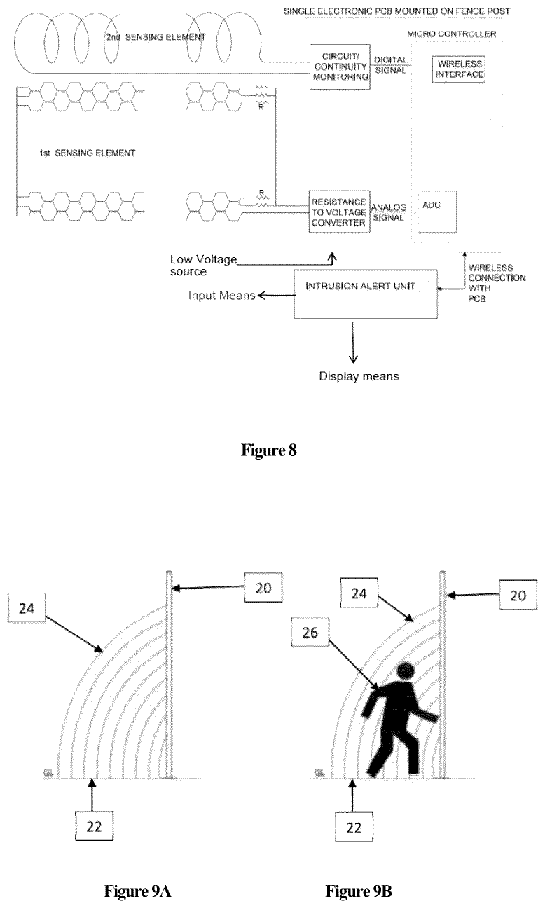

In its main embodiment, the present invention is for an intrusion detection system (1), to detect any intrusion attempt or cut of a fence (20) used as a barrier for protection, as seen at FIG. 1. It comprises of a 1^{st} sensing element extending between fence posts (11, 11′) and supported by accessories. The physical barrier, that is, the fence barrier itself, is used as a sensing element. The fence barrier, i.e., the 1^{st} sensing element could be made up of one or more components selected from wires, rods, bars, and may be in the form of a honeycomb mesh fabric, a chain link fence, a weld mesh fence, or concertina coils. The material used for all of the aforesaid is a conducting material like mild steel or stainless steel, aluminium, or copper (with or without galvanization) or any other electricity conducting material. The length of the sensing element could be supported by intermediate fence posts (12), straining posts (11), 11′) and/or end fence posts. (11′). Each length of the sensing element is secured to the straining fence posts (11) preferably with the help of clamps (55). The sensing element connected to a low voltage impedance detection system is insulated. The wires, rods, or bars used in the concertina coils, and the honeycomb mesh fabric, chain link fence, or weld mesh panels used to fabricate the fence, have an insulation coating (8). The choice of the coating material is critical to maintain the integrity of the insulation. The preferred coating is of polyvinyl chloride or poly amine 6. These materials provide a thin and effective insulation, and do not crack when the wires, rods, or bars are twisted or turned to a required configuration. The insulation (8) of the 1^{st} sensing element and the low voltage impedance detection system, prevents inadvertent electrocution and accidents in case any live object comes in contact with the sensing element. As seen at FIG. 8, the low voltage impedance detection system has a set of fixed resistors and an impedance monitoring assembly in connection with an intrusion alert unit (64). The intrusion alert unit comprises of an input means, a display means, an output means, and a central monitoring software.

The impedance monitoring assembly comprises of at least one circuit monitoring unit, resistance to voltage convertor, an analog-digital convertor (ADC), step down convertor, all in circuit connection with a microcontroller and housed within a PCB (44). The resistance to voltage convertor, measures the resistance and monitors the circuit. The step-down convertor aids in lowering the voltage source to the impedance monitoring assembly to desired voltage to meet the micro-controller and sensing element requirements of voltage. The microcontroller usually operates at about 2 to 5 volts. The voltage passing through the sensing element is about 3 to 10 volts, preferably 7 volts. The PCBs are preferably secured to the fence post and more specifically to the straining fence post (11).

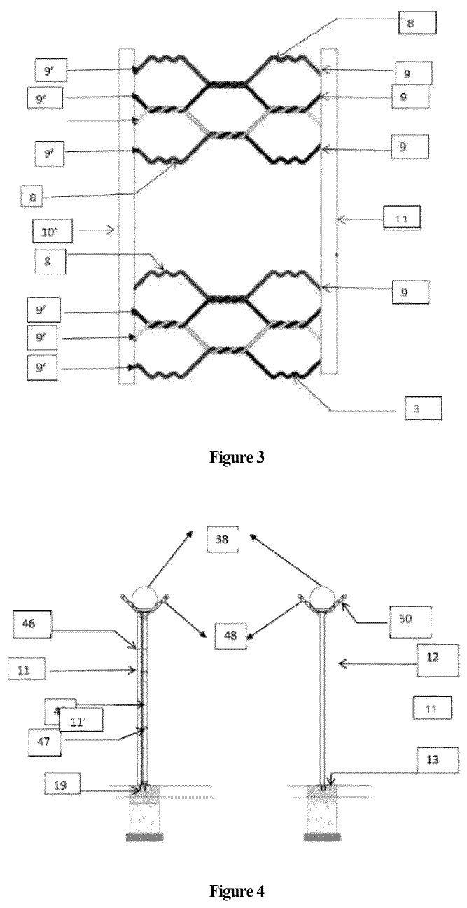

In a preferred embodiment of the invention, as seen in FIG. 2, the sensing element used is a honeycomb mesh fabric, which is made by knitting metal wires horizontally. As seen in FIG. 3, a standard honeycomb mesh fabric of an approximate height of 2 m is formed using around 40 horizontal wires. In the present invention, the wires are coated with an insulating material, to avoid the wires making electrical connections with each other. FIG. 3 is only representative of the horizontal wires and not indicative of the actual number of horizontal wires.

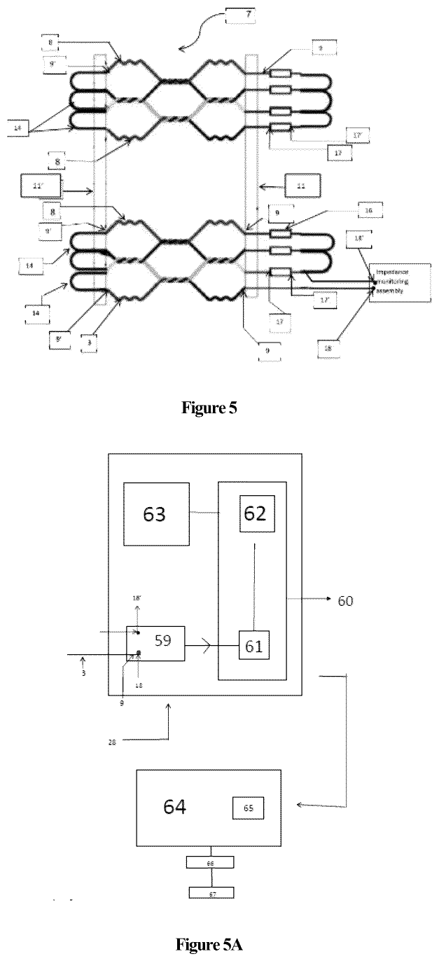

As seen in FIG. 1, the length of the honeycomb mesh fabric is stretched between and secured to a pair of straining fence posts (11) at either end by a stretching bar (43) and supported by intermediate fence posts (12) and diagonal supports (42) for additional support. Clamps (55) may be used additionally to secure the honeycomb mesh fabric to the straining fence post (11). The straining fence post (11) could be the end fence post (11′), corner fence posts, or a security gate fence post. For the sake of brevity, all the aforesaid fence posts together may be referred to as ‘fence posts’ (10). As seen in FIG. 4, the fence posts (11, 12) have a base plate (13), and the fence posts are bolted to the ground with bolts (19) passing through the base plate (13).

The honeycomb mesh fabric is usually commercially available in fixed lengths of 1 to 25 metres. For the purpose of this invention, the set of intertwined wires constituting the honeycomb mesh fabric is in horizontal alignment.

In a detailed aspect of the embodiment, as seem at FIGS. 5 and 5a, the 1^{st} end (9) of the first wire (3) of the honeycomb mesh fabric is connected to a 1^{st} terminal (18) of the resistance to voltage convertor which supplies the low voltage source (28). The 2^{nd} end (9′) of the wire is shorted to the 2^{nd} end (9′) of its immediately adjacent wire. Other than the first wire (3), each of the wires of the honeycomb mesh fabric, at their 1^{st} end (9) are connected to the 1^{st} end (17) of a fixed resistor (16), and the circuit is continued by shorting (14) the 2^{nd} ends of each of the remaining wires to the 2^{nd} ends of their immediately adjacent wire. All the wires of the honeycomb fence, remain in circuit connection through their respective fixed resistors which are also shorted at their respective 2^{nd} ends (17′) with the 2^{nd} ends (17′) of the immediately adjacent resistors (16) in the series. The horizontal wires are connected with each other through the fixed resistors (16) at the end of each horizontal wire in such a way that electrically, they represent a continuous electrical circuit. The first of the fixed resistors (16) at its 2^{nd} end (17′) is connected to the 2^{nd} terminal (18′) of the resistance to voltage convertor through a connection interface. The resistors at the end of each wire are all lodged at a primary termination block (46) and secured to the straining fence post (11), along the stretcher bar (43). The shorted 2^{nd} ends (9′) of all the horizontally aligned wires are lodged at the secondary termination block (47) of the other of the pair of straining fence post (11′).

Instead of every wire, alternate wires, or sequential interval of wires could be connected to a resistor, and the circuit continued by shorting (14) the wires appropriately, such that all the wires of the length of the honeycomb mesh fabric (7) are connected to form a continuous circuit.

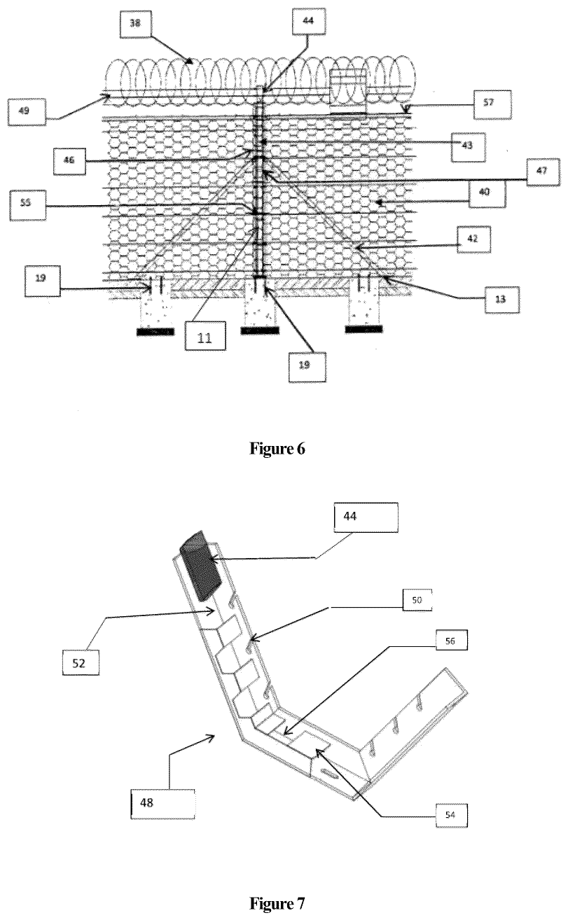

In a modified embodiment of this invention, as seen in FIG. 7, the fence posts (10, 11, 11′, 12) have upwardly extending Y arms (48), to support lengths of the 2^{nd} sensing elements between two straining fence posts (11), and are supported by intermediate posts (12). The straining fence post (11) could also be one among end posts, corner posts, or security gate fence posts (10, 10′). The 2^{nd} sensing element could be a chain link, honeycomb mesh fabric, weld mesh panel, or concertina coil. A seen in FIG. 8, the ends of the length of the 2^{nd} sensing element are in circuit connection with a circuit monitoring unit (63) and the microcontroller (60) within the impedance monitoring assembly. As can be seen in FIG. 7, the Y arms (48) are recessed, and the PCBs (44) housing the impedance monitoring assembly are secured within the recesses (52). The Y arms (48) have notches (50) for hooking the concertina coils (40). Depending on the diameter of the concertina coils used, they could be hooked on a higher, lower or middle notch. If the fence post is a straining fence post, the cable (56) from the PCB runs within the restraints (54) in the Y arm (48) to a cable tray (57) as shown in FIG. 6. The PCB (44) of each of the straining fence posts (11) is connected to the PCB of the subsequent straining fence post by a cable (56) which runs through the cable tray (57). Concertina coils are preferred as the 2^{nd} sensing element (40), and the ends of each length of the concertina coils are in circuit connection with the 2^{nd} circuit monitoring unit as shown in FIG. 8. For additional protection, a barbed wire (49) may run along the length of the concertina coils, so as to deter the cutting of the concertina coils.

In a sophisticated embodiment of this invention, the microcontroller within the impedance monitoring assembly is in wireless connection with the intrusion alert unit (64), through a wireless interphase (62) as shown in FIG. 8.

The disclosed intrusion detection system (1), works on the premise that whenever there is any disturbance at the fence, i.e., the sensing element in the present case, even as a person approaches the fence, the impedance characteristics change.

Because of the conducting nature of the material used, the fence or sensing element as a whole presents an electrical impedance having resistive, inductive and capacitive characteristics.

The disturbance in the form of cutting of the fence wires leads to a condition of “open circuit” or very large impedance as compared to a minor impairment of “short circuit” or very low impedance. Thus, when a fence wire is cut, there is a sudden change in the impedance characteristics.

With the intrusion detection system (1) disclosed herein any cut of the sensing elements is detected by the circuit monitoring units and the extent of the cut can also be monitored as a result of the change in resistance of the wire or segment.

In a working embodiment of this invention, any cut in the elements or wires of the honeycomb mesh fabric, would alter the resistance offered by the wires of the honeycomb fabric. As can be seen in FIG. 5a, the variation in the resistance is monitored and measured by the resistance to voltage convertor (59), the readings are converted from analog to digital by an analog to digital convertor (ADC) (61), and conveyed to the microcontroller (60) in the impedance monitoring assembly (58). The microcontroller conveys the readings to a remote intrusion alert unit (64) where the readings are processed by the central monitoring software and displayed on the display means (67). The resistance to voltage convertor (59) monitors the circuit in the 1^{st} sensing element (38) and measures the change in the resistance whenever there is a cut to the fence or the fence is completely breached. Any cut to the 2^{nd} sensing element is monitored by the 2^{nd} circuit monitoring unit and conveyed to the microcontroller, which, in turn also conveys these readings to the input means (65) of the intrusion alert unit. Where the impedance monitoring assembly is in a wireless connection with a remote intrusion alert unit, the readings are conveyed by the microcontroller through the wireless interphase to the intrusion alert unit, where the readings are processed by the central monitoring software, and the output (66) is displayed on the display means (67).

The present invention helps detect intrusion when the attempt starts. The system enables detection of the intrusion even if a single wire is cut, as well as subsequent cuts.

As seen in FIG. 5, other than the first wire (3), each horizontal wire at its 1^{st} end (9), is connected to a fixed resistor (16) which is also represented as “R” in FIG. 8. The 2^{nd} ends of all the wires are connected to each other. The 2^{nd} end of the fixed resistor R (16) is connected to each other. The overall resistance between the points is expected to be R/(n−1) where n is the number of horizontal wires. When one or more wires are cut, there is a corresponding change in the resistance—the resistance value increases. This change in resistance is measured. From the value of the change in resistance, the number of wires cut can be found out. The system provides reliable intrusion detection for one or more cuts in the fence.

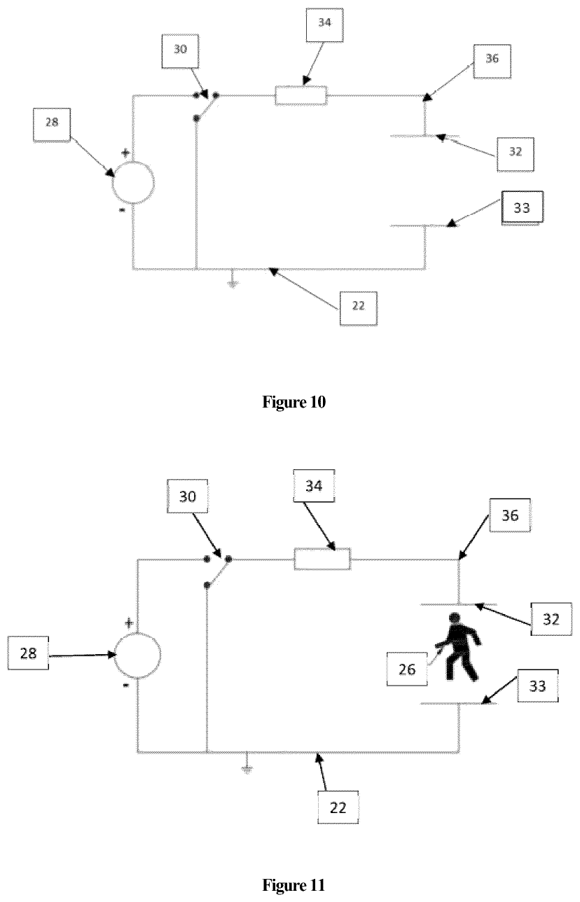

In an advanced embodiment of this the invention, when the fence posts (10, 10′) are mounted on the ground surface (22), the 1^{st} sensing element acts as a first plate (20) and the ground surface acts as a second plate to create a virtual capacitor circuit (24) between the two as shown in FIGS. 9 and 10. In such an event, when an object (26) approaches the 1^{st} sensing element, there is a change in capacitance value, because of the interruption in the virtual capacitor circuit (32, 33) which is detected by the virtual fence capacitor circuit monitor, which conveys the values to the microcontroller, and the microcontroller conveys the values to the intrusion alert unit where the values are processed by the central monitoring software, and displayed on the display means (FIG. 11). A multimeter could also be used to measure the change in the capacitance value. In such a case, one terminal is connected to the ground and the other terminal is connected to the 1^{st} sensing element (38), and preferably operated through a switch (30). In case the microcontroller in the impedance measurement unit is in remote wireless connection with the intrusion alert unit, the readings are conveyed through a wireless interphase to the intrusion alert unit.

The intrusion detection system detects the intruders ‘near’ the fence barrier or the 1^{st} sensing element or ‘on’ the fence barrier or 1^{st} sensing element, based on the theory of capacitance. The capacitance between two parallel plates depends upon the area of the plate, the dielectric between them, and the distance between the plates.

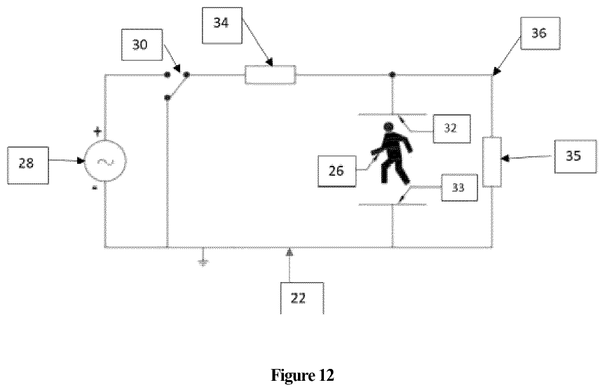

As shown in FIG. 12, the fence installed on the ground, functions as the first plate (20) of a parallel plate capacitor with the ground or earth (22) as another plate. The fence is generally installed perpendicular to the ground and has a large area. Air provides dielectric medium, air thus forming weak but detectable capacitance. The fence metal has to be electrically isolated from the ground. When an intruder (26) having loose contact to the ground (barefoot, wearing shoes, or other footwears) approaches the fence barrier or 1^{st} sensing element, there is a change in the capacitance between the two plates as the dielectric between them changes.

The measurement of the change in the capacitance to detect an intruder was carried out using Atmel's inbuilt Q-touch feature, by calculating the charge and discharge time, and impedance measurement by passing high frequency signals to the virtual fence capacitor circuit.

Alternatively, the capacitance is measured by calculating the charge and discharge time. Charging discharging time of any capacitor can be easily measured by recording the time taken for charging of the capacitor. The system can be utilised for any type of fencing, and more particularly for a honeycomb fence setup. The fence fabric is built by insulated galvanised iron (GI) wires. Both ends of the honeycomb fabric are electrically shorted on both ends of the fabric, and it is insulated from the post also. The entire 1^{st} sensing element (38) functions as a plate of the capacitor. For the electrical connection of the measurement circuit, the earthing or the minus point is connected to the ground (22), through the bolt (19) on the fence post, and if necessary, through additional wires.

In the circuit shown in FIG. 11, point (28′) is the power supply of 3.3 volt, point 30 is an electronic switch controlled by a microcontroller. When the switch is on and connected to a positive terminal, the capacitor starts charging. The charge time depends on the value of the resistor (34) and the variable virtual capacitor (capacitor plate (20 and 22)).

The capacitor charging equation is represented as

$$Vo = V c c ( 1 - e \hat{} ( - t / RC ) )$$

wherein,
Vo is voltage across capacitor
Vcc is supply voltage
t is the elapsed time since the application of supply voltage
RC is time constant (R is represented as apoint on (20) as seen in FIG. 9)
C is the capacitance between point 20 and point 22 of the capacitor plate.

When an intruder (26) approaches the fence (20), the dielectric between the two points 32 and 33 changes. Hence, the capacitance also changes and the charge time also varies, and this variation is measured at point (36).

Along approximately 6 meters length and around 1-5 meters high, of the honeycomb fence, when no human is present close to the fence, the capacitance value was found to be 0.9 nF and it increases by 40 pf when intruder tries to climb on the fence. The change happens gradually as the intruder moves closer to the fence and finally touches the fence.

This variation in charge time is identified as intrusion alert. However, this approach has certain limitations. It can be affected by vegetation and insulation breaking of honeycomb wire. Dense vegetation can result in very small change in capacitance when intruders (26) approach the fence (20). Any damaged insulation will result in electrical leakage of voltage and current between point 32 and 33, and complete failure of intrusion detection.

One more embodiment of the invention counters and overcomes the challenges of the above approach for intrusion detection. Instead of constant DC voltage, high frequency sine wave source 1 is used and a resistor (34) of the value 1000 ohms, is used in parallel with the virtual capacitor. This resolves the problem of voltage leaking. The experiments with different soil types have proved that the resistance between fence posts (which are directly connected to ground (22) and most likely the path of leakage current) and the ground never go below the 2000 ohms. The resistor (35) of a value of 2000 ohms, is introduced for measuring the impedance at the point (36) (FIG. 11), and the sine wave helps detect small and large variations of the changes in the capacitance, as the rest of the circuit becomes a simple voltage divider circuit. The system is successful for capacitive intrusion detection on other fences as well, for example, Weldmesh, Chain link, etc.

### EXAMPLES

### Example: Effect of Using Different Values of Series Resistors that are Connected to the Fence Wire Segments

The choice of a value of a resistor used in a series with fence wire segments decides whether the combined resistance of the segments is such that the loss of integrity of one segment leads to variation in the combined effect that is measurable by the system.

Measurement of the combined resistance was done with the following values of the resistors connected in series with fence wire segments: 22 k, 10 k, 4.7 k, 2.2 k, 1 k.

The combined resistance was connected in series with the current sensing resistor, and the current was measured as an indicator of the combined resistance. A 10-bit ADC (61) was used to convert the analog values to digital. This method was used because in actual measurement, the effect of the analog circuit and the ADC will have an effect on the measurement.

For fences having 20 to 40 horizontal segments (which will be the case for most common fence heights), the combined resistance offered when a 10 k resistor is used in series is such that there are least measurement errors.

For other resistor values, following effects were noted-If the resistor value is significantly more than 10 k, the current values are less, and the values become comparable to the input bias current of the signal conditioning circuit, thereby distorting the readings.

If the resistor values are significantly less than 10 k, the current variation is less and the current value is more, leading to loss of resolution and a situation where the ADC converter reaches its upper limit.

For normal fence heights (1.8 m to 2.4 m) where the number of horizontal wire segments vary from 20 to 40, use of 10 k resistor in a series, gives optimum measurement result, that can reliably infer whether the fence wire integrity is compromised or not.

### Example: Effect of Use of Different Coating Types for the Horizontal Fence Wires

The ability of a system to detect whether the integrity of a single fence segment is compromised or not depends upon the effectiveness of the insulation on the wires. Various insulation coatings are possible. It is important to identify the appropriate coating for the current application.

The fence wires were coated with different coatings selected from
1. PPC (Poly (propylene carbonate))
2. PVC coating (Polyvinyl chloride coating)
3. PA6 coating (Polyamine 6 coating)

Each sample of the coated wires was used to build the honeycomb mesh. The integrity of the insulation was measured using a multi-meter. The main criterion is to ensure that the coating does not develop cracks when the wires are twisted during the weaving process.

It was observed that the PPC mesh built did not provide insulation. The PVC coating provided the insulation, but in the process of twisting, at some of the places, the coating cracked exposing the core wire. The cracked coating when exposed to water ingress could lead to shorting (14) of adjacent wires. With PA6 coating, it was found that the insulation quality was excellent and the coating was not affected by twisting operation. The PA6 coating was found to be most suitable from the point of durability and requirement of the application.

### Example: Effect on Capacitance Offered by Fence Fabric as a Person Approaches/Touches the Fence

The capacitance offered by the fence fabric is expected to change when a person or an object approaches the fence. This is because of a change in the dielectric between the fence elements and the ground. Under normal conditions where there is no person present in the vicinity of the fence, air is the dielectric. When a person approaches the fence, there is a change in the capacitance. The change in the capacitance is measured. The readings are repeated in order to conclude whether the capacitance characteristics can be used to infer whether a person is approaching the fence.

Capacitance is measured between the fence wires. The alternate wires of the fence are connected to the positive terminal and the remaining wires are connected to the negative terminal end. The negative terminal is also grounded. The capacitance value is measured by the microcontroller.

The capacitance value is measured when there is no person in the vicinity of the fence, and when there is a person at a distance of 5 m, 4 m, 3 m, 2 m and 1 m from the fence.

Measurements are repeated when a person is present on the opposite side of the fence at a distance of 5 m, 4 m, 3 m, 2 m and 1 m from the fence.

The capacitance value measured when there is no person in the vicinity of the fence is about 0.5 pF. As a person approaches the fence, the capacitance value increases from 1 pf at 5 m, 1.5 pf at 4 m, 2 pf at 3 m, 2.5 pf at 2 m and 3 pf at 1 m. The results obtained are same for approach of a person from either side.

Capacitance values show a correlation between the distance of the person from the fence. The capacitance measurement does not differentiate the side from which the person is approaching.

The low voltage intrusion detection system of the present invention can detect both an individual touching the live wire as well as a cut of the fence barrier or 1^{st} sensing element resulting in a complete short circuit between two or more wires or an open circuit in one or more wires of the sensing element forming the fence structure, as an intrusion attempt is being made. The present invention can also detect the presence of an object or intruder approaching or close to the fence barrier. Most importantly, because of the low voltage used, it meets safety standards. The remote intrusion alert unit associated with this system, makes its use attractive in remote and vast areas which require protective fencing.

1. An intrusion detection system (1) for fencing (20) having an electricity conducting 1^{st} sensing element (38) extending horizontally between fence posts (10, 10′) and the sensing element connected to a low voltage impedance detection system, characterised by the sensing element being insulated (8) and the impedance detection system comprising a set of fixed resistors (16) and an impedance monitoring assembly (58) in connection with a remote intrusion alert unit (64).

2. The intrusion detection system as claimed in claim 1, wherein the fence posts mounted on a ground surface (22), and a virtual capacitor circuit created by the sensing element (38) act as a first plate, and the ground surface (22) acts as a second plate.

3. The intrusion detection system as claimed in claims 1 and 2, wherein the remote intrusion alert unit (64) with a central monitoring software, comprising an input means (65), an output means (66) and a display means (67).

4. The intrusion detection system as claimed in claim 3, wherein the impedance monitoring assembly connected to a low voltage source (28) having a resistance to voltage convertor (59), an anolog-digital convertor (ADC) (61) within a microcontroller (60), and a wireless interface (62), and are in circuit connection and placed within a printed circuit board (PCB) (44).

5. The intrusion detection system as claimed in claims 1 and 4, wherein the 1^{st} sensing element (38) is made up of a component selected from wires, rods, bars, or combinations thereof.

6. The intrusion detection system as claimed in claims 1 and 4, wherein the 1^{st} sensing element is (38) selected from a honeycomb mesh fabric, a chain link fence, a weld mesh fence, and concertina coils.

7. The intrusion detection system as claimed in claims 5 and 6, wherein the 1^{st} sensing element is insulated using polyvinyl chloride or polyamide 6.

8. The intrusion detection system as claimed in claim 7, wherein the 1^{st} sensing element (38) is a length of honeycomb mesh fabric made of a set of adjacently spaced insulated wires between a first wire (3) and a last wire, all in horizontal alignment, the wires having a 1^{st} end (9 and a 2^{nd} end (9′), with the lengths of honeycomb mesh fabric (7) being extended by stretch bars (43) between pairs of fence posts which are straining fence posts (11).

9. The intrusion detection system as claimed in claim 8, wherein the the 1^{st} end (9) of the first wire of each length of the honeycomb mesh fabric is connected to a low voltage source (28) through a 1^{st} terminal of the resistance (18) to the voltage convertor and the 2^{nd} end (9′) of the first wire shorted (14) to the 2^{nd} end of its immediately adjacent wire (8), and the first end (9) of such adjacent wire being connected to a 1^{st} end (17) of the first of a series of fixed resistors (16) and a 2^{nd} (17′) end of such resistor connected to a 2^{nd} terminal (18′) of the resistance to voltage convertor, each of the remaining wires also being shorted (14) at its 2^{nd} end (9′) to its respective adjacent wire (8) and at its 1^{st} end (9) to its respective fixed resistors (16), the 2^{nd} end (17′) of all the resistors being shorted to its immediately adjacent fixed resistor (16), to form a continuous electrical circuit.

10. The intrusion detection system as claimed in claim 9, wherein the shorted 2^{nd} ends (9′) of each of the wires are secured at a secondary termination block (47) on one of the pair of the straining fence post (11) and the resistors (16) at the 1^{st} end (9) of each wire are lodged at a primary termination block (46) and secured on the other of the pair of the straining fence post (11).

11. The intrusion detection system as claimed in claim 10, wherein the PCBs (44) are secured on the straining fence post (11).

12. The intrusion detection system as claimed in claims 1 and 10, wherein the fence posts have upwardly extending Y arms (48) with recesses (52), and the Y-arms (48) support 2^{nd} sensing elements (40) between two or more fence posts (10,11), and the 2^{nd} sensing element (40) are in circuit connection to a circuit monitoring unit and the microcontroller within the PCB (44).

13. The intrusion detection system as claimed in claim 12, wherein the 2^{nd} sensing element is a concertina coil (40), with two ends of the concertina coil in circuit connection to the circuit monitoring unit and the microcontroller within the PCB (44).

14. The intrusion detection system as claimed in claims 9, 12 and 13, wherein the PCB (44) is secured within the recess (52) of the Y arm (48).

15. The intrusion detection system as claimed in claim 14, wherein the PCBs (44) on the straining fence post (11, 11′) are connected to such other PCB on another straining fence post by a cable (56).

16. The intrusion detection system as claimed in claims 11 and 15, wherein the microcontroller in the PCB (44) is in wireless connection with the intrusion alert unit.

17. The intrusion detection system as claimed in claim 16, wherein the low voltage source (28) supplies current of 2 Volts to 25 Volts.

18. A method of intrusion detection using the intrusion detection system as claimed in any of claims 1 to 17, wherein a variation in resistance arising from contact or cut on the 1^{st} sensing element (38) is measured by the resistance to the voltage convertor, converted to a digital reading by the analog-digital convertor and conveyed to the microcontroller, and further conveyed to the intrusion alert unit, processed by the central processing software and an intrusion evaluation is displayed on the display means.

19. A method of intrusion detection using the intrusion detection system as claimed in any of claims 1 to 17, wherein a cut of the 2^{nd} sensing element (40) is detected by the circuit monitoring unit and conveyed to the microcontroller, and further conveyed to the intrusion alert unit, processed by the central processing software, and an intrusion evaluation is displayed on the display means.

20. A method for apprehending intrusion using the intrusion detection system as claimed in claims 1 to 17, wherein a change in the virtual fence capacitor circuit as a result of an object approaching the 1^{st} (38) and 2^{nd} (40) sensing elements mounted to a fence post (10, 10′) on the ground (22), is measured by the microcontroller, and further conveyed to the intrusion alert unit by the microcontroller, processed by the central processing software, and an intrusion evaluation is displayed on the display means.

21. A method for apprehending intrusion using intrusion detection system as claimed in claims 1 to 17, wherein a variation in resistance resulting from a contact or cut to the 1^{st} sensing element (38) is measured by the resistance to the voltage convertor (59), converted to a digital reading by the analog-digital convertor (61), and conveyed to the microcontroller; a cut to the 2^{nd} sensing element (40) is detected by the circuit monitoring unit (63) and conveyed to the microcontroller (60), and a change in the virtual fence capacitor circuit as a result of an object approaching the 1^{st} (38) and 2^{nd} (40) sensing elements when the fence post (10, 10′) is mounted on the ground (22), is detected by the microcontroller (60), and further conveyed to the intrusion alert unit (64) by the microcontroller, processed by the central processing software, and an intrusion evaluation is displayed on the display means (67).
